(19) United States
(12) Patent Application Publication
(10) Pub. No.: US 2008/0160740 A1
(43) Pub. Date: Jul. 3, 2008

(54) Method For Manufacturing Semiconductor Device

(76) Inventors: Hyun Ahn, Seoul (KR); Chang Youn Hwang, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/771,682

(22) Filed: Jun. 29, 2007

(30) Foreign Application Priority Data
Dec. 28, 2006 (KR) 10-2006-0137029

(51) Int. Cl. H01L 21/3205

(52) U.S. Cl. 438/586; 257/E21.294

(57) ABSTRACT

A method for manufacturing a semiconductor device comprises forming a SEG layer in a bottom of a storage node contact hole, and forming a spacer at a sidewall of a storage node contact hole and a bit line contact hole, thereby preventing expansion of the bottom of the bit line contact hole. Also, the method prevents a short phenomenon of a bit line contact plug and a recess gate, thereby improving an insulating characteristic of the device. The thickness of the spacer of the sidewall of the recess gate can be increased to protect the recess gate.

### CROSS-REFERENCE TO RELATED APPLICATION

The priority of Korean patent application number 10-2006-0137029, filed on Dec. 28, 2006, is hereby claimed, and its disclosure is hereby incorporated by reference herein in its entirety.

### BACKGROUND OF THE INVENTION

The present invention generally relates to a method for manufacturing a semiconductor device, and more specifically, to a method for forming a Landing Plug Contact (LPC) of a semiconductor device.

Due to increases in integration of semiconductor devices, a gap between conductive lines such as gates has become smaller to reduce a contact process margin.

A Self-Aligned Contact (SAC) process is performed in order to secure the contact process margin.

When a storage node contact hole and a bit line contact hole are formed, a gate spacer can be damaged, and an interlayer insulating film is not removed, thereby generating a SAC failure.

Since an epitaxial layer is not formed in the bottom of the bit line contact hole, the bottom of the bit line contact hole is extended by a washing solution in a post washing process for removing residuals in formation of the storage node contact hole. The bottom of the bit line contact hole is further extended by a pre-washing process before filling a conductive film in the storage node contact hole and the bit line contact hole.

A recess gate becomes shorted with the bit line contact plug to generate a SAC failure.

### BRIEF SUMMARY OF THE INVENTION

Various embodiments of the present invention are directed at providing a method for fabricating a semiconductor device which prevents a SAC failure generated between a bit line contact plug and a recess gate.

According to an embodiment of the present invention, a method for manufacturing a semiconductor device comprises: forming a plurality of gates, at least one gate including a recess region over a semiconductor substrate; forming an interlayer insulating film to fill a portion between the gates; etching the interlayer insulating film to form a storage node contact hole and a bit line contact hole; forming a contact spacer at a sidewall of the storage node contact hole and the bit line contact hole; and filling a conductive film in the storage node contact hole and the bit line contact hole to form a storage node contact plug and a bit line contact plug.

### BRIEF DESCRIPTION OF THE DRAWINGS

FIGS. 1a through 1c are cross-sectional diagrams illustrating a method for manufacturing a semiconductor device according to an embodiment of the present invention.

### DETAILED DESCRIPTION OF THE EXEMPLARY EMBODIMENTS

The present invention will be described in detail with reference to the accompanying drawings.

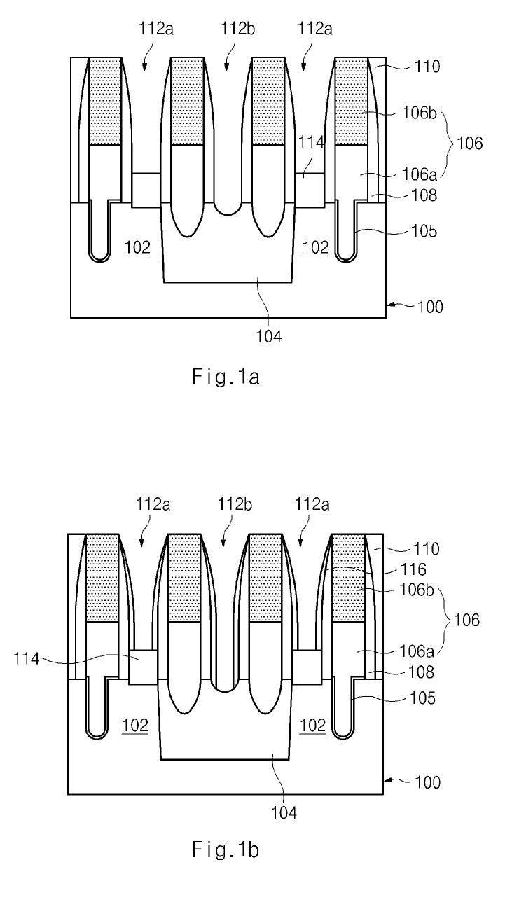

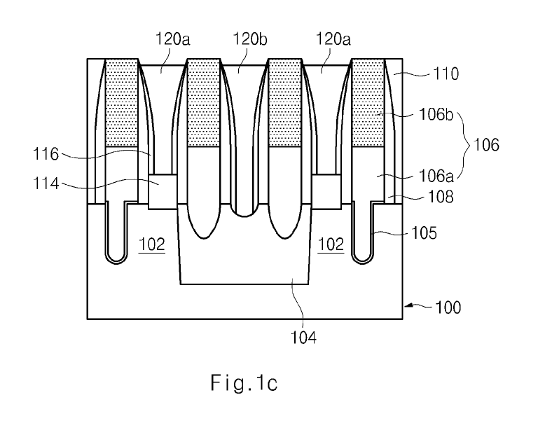

FIGS. 1a through 1c are cross-sectional diagrams illustrating a method for manufacturing a semiconductor device according to an embodiment of the present invention.

A device isolation film 104 which defines an active region 102 is formed over a semiconductor substrate 100.

The semiconductor substrate 100 is etched at a given thickness by a photo-etching process with a recess mask, to form a recess region, and a gate insulating film 105 is formed in the recess region. A gate electrode layer and a gate hard mask layer are formed over the gate insulating film 105. The gate electrode layer has a stacked structure including a gate poly silicon layer and a gate tungsten layer.

The gate electrode layer and the gate poly silicon layer are etched by a photo-etching process with a gate mask, to form a recess gate 106 including a gate electrode pattern 106a and a gate hard mask pattern 106b.

A first nitride film is formed over the resulting structure including the recess gate 106. An etching and washing process is performed to form a gate spacer 108 at a sidewall of the recess gate 106.

An interlayer insulating film 110 is formed over the resulting structure. A SAC etching process is performed on the interlayer insulating film 110 with a landing plug contact mask, to form a storage node contact hole 112a and a bit line contact hole 112b.

A Selective Epitaxial Growth (SEG) layer 114 is formed in the bottom of the storage node contact hole 112a by a SEG method. The SEG layer 114 is formed to reduce contact resistance. Its growth is inhibited so that the SEG layer 114 is not formed in the bottom of the bit line contact hole 112b.

With reference to FIG. 1b, a second nitride film is formed over the resulting structure. An etching and washing process is performed to form a contact spacer 116. The contact spacer 116 preferably is formed to have a thickness ranging from about 20 Å to about 100 Å. The etching process of the second nitride film preferably is performed under a gas atmosphere selected from the group consisting of CF₄, CHF₃, O₂, Ar, and combinations thereof. The etching target of the second nitride film preferably ranges from about 100 Å to about 200 Å.

With reference to FIG. 1c, a conductive film is filled in the storage node contact hole 112a and the bit line contact hole 112b. The contact spacer 116 is used as an etching barrier film for preventing expansion of the bottom of the bit line contact hole 112b in a washing process before a storage node contact plug 120a and a bit line contact plug 120b are formed.

A planarization process is performed to form a storage node contact plug 120a and a bit line contact plug 120b. The planarization process planarizes the upper portion of the conductive film, and separates the storage node contact plug 120a from the bit line contact plug 120b.

As described above, according to an embodiment of the present invention, a method for manufacturing a semiconductor device comprises forming a SEG layer in a bottom of a storage node contact hole, and forming a spacer at a sidewall of a storage node contact hole and a bit line contact hole, thereby preventing expansion of the bottom of the bit line contact hole. Also, the method prevents a short phenomenon of a bit line contact plug and a recess gate, thereby improving an insulating characteristic of the device. The thickness of the spacer of the sidewall of the recess gate is increased to protect the recess gate.

The above embodiments of the present invention are illustrative and not limitative. Various alternatives and equivalents are possible. The invention is not limited by the lithography steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
forming a plurality of gates, at least one gate including a recess region over a semiconductor substrate;
forming an interlayer insulating film to fill a portion between the gates;
etching the interlayer insulating film to form a storage node contact hole and a bit line contact hole;
forming a contact spacer at a sidewall of the storage node contact hole and the bit line contact hole; and
filling a conductive film in the storage node contact hole and the bit line contact hole to form a storage node contact plug and a bit line contact plug.

2. The method according to claim 1, wherein the step of forming a contact spacer comprises:
forming a nitride film over the resulting structure; and
performing an etching and washing process on the nitride film.

3. The method according to claim 2, wherein the etching process of the nitride film is performed under a gas atmosphere selected from the group consisting of CF₄, CHF₃, O₂, Ar, and combinations thereof.

4. The method according to claim 2, wherein the etching target of the nitride film ranges from about 100 Å to about 200 Å.

5. The method according to claim 1, wherein the contact spacer has a thickness ranging from about 20 Å to about 100 Å.

6. The method according to claim 1, further comprising forming a SEG layer in the bottom of the storage node contact hole by a selective epitaxial growth method.

7. The method according to claim 1, further comprising performing a washing process after forming the contact spacer.

8. The method according to claim 1, wherein the step of forming a storage node contact hole and a bit line contact hole includes etching the interlayer insulating film by a self-aligned contact etching method.
